(19) United States
(12) Patent Application Publication
(10) Pub. No.: US 2008/0038097 A1
(43) Pub. Date: Feb. 14, 2008

(54) APPARATUS FOR CLAMPING A STACK OF TRAYS

(75) Inventors: Ho-Seong KIM, Gyeonggi-do (KR); Eduard KURGI, Gyeonggi-do (KR); Jung-Hyeon KIM, Gyeonggi-do (KR); Hee-Jin KIM, Gyeonggi-do (KR); No-Shin PARK, Chungcheongnam-do (KR); Jae-Nam LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/776,953

(22) Filed: Jul. 12, 2007

(30) Foreign Application Priority Data
Aug. 8, 2006 (KR) 2006-0074659

(51) Int. Cl. H01L 21/683; H01L 21/677

(52) U.S. Cl. 414/217.1

(57) ABSTRACT

Provided is an apparatus for clamping a stack of trays that allows automation and prevents distribution of particles or foreign materials during a semiconductor fabrication process. In one embodiment, the apparatus includes a frame body surrounding the stack of trays, a plurality of belt drums, and a hook. Each belt drum is attached to one side of the frame body has a belt and spiral spring. The belt is structured to securely surround the stack of trays using the elastic tension of the spiral spring member mounted in the belt drum. The hook is structured to be rotatably connected to the frame body and slid under a bottom surface of the stack of trays to secure the stack of trays.

### CROSS-REFERENCE TO RELATED PATENT APPLICATION

This application claims the benefit of Korean Patent Application No. 10-2006-0074659, filed on Aug. 8, 2006, in the Korean Intellectual Property Office, the disclosure of which is incorporated herein in its entirety by reference.

### BACKGROUND

1. Field of the Invention

The present invention relates to tools used in the fabrication of semiconductor devices, and more particularly, to an apparatus for clamping together a stack of trays used in the packaging, handling, and transporting semiconductor packages.

2. Description of the Related Art

Semiconductor packages are typically handled and transported between processes in lots during manufacture. To allow for easy handling and transportation during assembling and electrical inspection, trays are used to house the semiconductor packages. Trays are also used to protect the semiconductor packages against external shocks during transportation and packaging.

The Joint Electron Device Engineering Council (JEDEC) standard defines the specifications of tray designs. JEDEC trays have a plurality of pockets to receive a predetermined number of semiconductor packages. That is, a plurality of semiconductor packages can be handled and transported in the JEDEC trays. Typically, several trays can be stacked on one another during storage for assembling and electrical inspection of semiconductor packages.

FIG. 1 is a perspective view of a conventional clamping apparatus 12 for clamping a stack of trays 10.

Referring to FIG. 1, the semiconductor packages are housed in the trays 10 for handling and transportation.

While the trays are used to house and protect the semiconductor packages, they must also be easily separable from each other so that the semiconductor packages can be efficiently loaded and unloaded from the trays during various manufacturing processes. However, because the trays can be easily separable from each other by an external force, there is also a risk that the trays may separate at an undesirable time during the manufacturing process where the semiconductor packages may drop out of the trays or be otherwise damaged. To prevent this risk, the conventional clamping apparatus 12 clamps the stack of trays 10 using a textile band with a hook-and-loop attachment mechanism, such as Velcro tape, to attach and secure the clamping apparatus 12 to itself. A lot information card 14 containing product information is also attached to one of the trays 10 or inserted beneath the clamping apparatus 12 to identify product information on the stack of trays 10.

The conventional clamping apparatus 12 using the textile band attached with the Velcro tape is inexpensive, small, and is easy to handle. The apparatus can also band various numbers of trays into a stack because of the flexible attachment means provided by the Velcro tape.

However, this conventional tray clamping apparatus having the above-mentioned construction has several drawbacks.

One drawback of the conventional tray clamping apparatus is that automation is difficult to obtain because the conventional clamping apparatus 12 must be applied and removed manually. Most manufacturing equipment and facilities used for the manufacture of semiconductor packages are currently designed to support automation. Thus, this manual operation is a key stumbling block in efforts to automate the entire manufacturing process.

Another drawback is that the conventional apparatus requires an operator to hold, rotate, or move a bulky stack of trays when banding the trays into a stack of trays or separating the trays by removing the band. This may be awkward for the operator and requires a large amount of time and human effort. The absence of a separate hand grip also makes handling a stack of trays more cumbersome.

Semiconductor fabrication processes generally require a high level of cleanliness. To achieve a certain level of cleanliness, the amount of contaminants and particles should be strictly regulated. Yet another drawback of the conventional tray clamping apparatus is that it is not suitable for fabrication of many types of semiconductor devices because contaminants and particles are distributed during the attachment and detachment of the Velcro.

Yet still another drawback is that it requires the use of a separate carrier box for handling or transporting stacks of trays with heights that vary depending on the number of semiconductor packages in a lot during the fabrication of the semiconductor packages.

During a semiconductor package fabrication process, a lot information card with barcodes is used to recognize lot information corresponding to each stack of trays. However, because a lot information card is inserted in a location randomly selected by an operator, the location may vary for each stack of trays, thus making it difficult for lot information to be automatically recognized using automation equipment and facilities.

### SUMMARY

The present invention provides a novel apparatus for clamping a stack of trays that allows for automation and automatic recognition of product information and eliminates the cumbersomeness of the manual operations of an operator.

According to an embodiment of the present invention, an apparatus for clamping a stack of trays including at least one tray includes a frame body surrounding the stack of trays, a plurality of belt drums, and a hook. Each belt drum is attached to one side of the frame body and includes a belt and spring member. The belt is structured to surround the stack of trays to secure the stack of trays using the elastic tension of the spiral spring member. The hook is rotatably connected to the frame body and is structured to slide under a bottom surface of the stack of trays.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a conventional apparatus for clamping a stack of trays;

FIG. 2 is a perspective view of an apparatus for clamping a stack of trays according to an embodiment of the present invention;

FIG. 3 is a side view of the hook shown in the apparatus of FIG. 2;

FIGS. 4A through 4C are side views illustrating the operation of the hook in the apparatus of FIG. 2;

FIGS. 5A and 5B are side views illustrating the operation of a hook-fixing unit in an apparatus for clamping a stack of trays according to another embodiment of the present invention;

FIGS. 6A and 6B are side views illustrating the operation of a hook-fixing unit in an apparatus for clamping a stack of trays according to another embodiment of the present invention;

FIGS. 7 though 9 are a front view, a plan view, and a side view, respectively, illustrating states in which a tray clamping apparatus has clamped trays together according to another embodiment of the present invention;

FIG. 10 is a perspective view of an apparatus for clamping a stack of trays according to another embodiment of the present invention;

FIG. 11 is a side view illustrating the operation of a belt drum in the apparatus of FIG. 10;

FIG. 12 is a perspective view of an apparatus for clamping a stack of trays according to another embodiment of the present invention;

FIG. 13 is a side view illustrating the operation of a belt drum in the apparatus of FIG. 10 according to an embodiment of the present invention;

FIG. 14 is a side view illustrating the shape and function of the hooks in the apparatuses of FIGS. 10 and 12 according to an embodiment of the present invention; and

FIGS. 15A and 15B are side views illustrating operation principles of the belt fixing units in the apparatuses of FIGS. 10 and 12 according to an embodiment of the present invention.

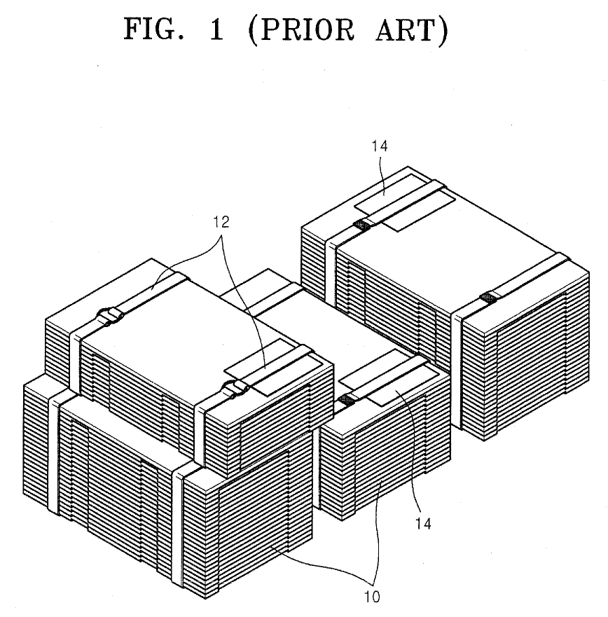

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

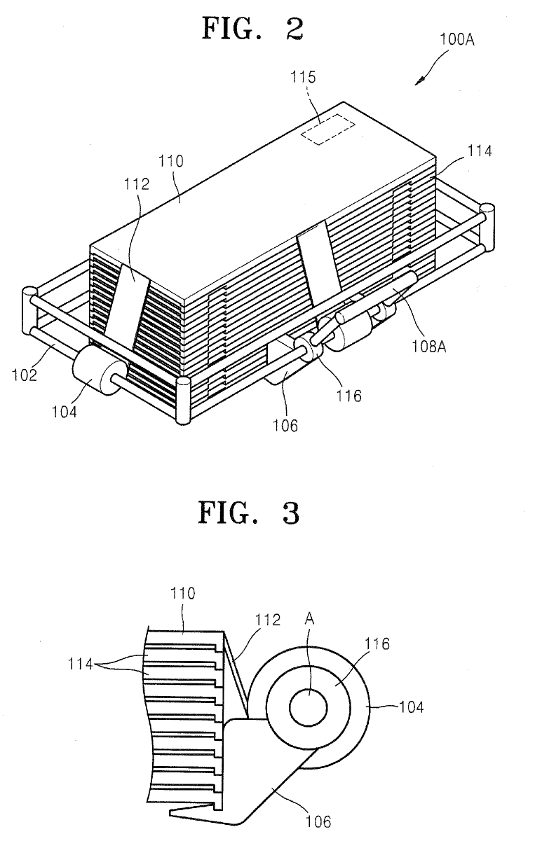

FIG. 2 is a perspective view of an apparatus 100A for clamping a stack of trays according to an embodiment of the present invention. Referring to FIG. 2, the apparatus 100A includes a substantially rectangular frame body 102 surrounding a plurality of trays 114 formed in a stack for handling and fixing the stack of trays 114 so as to protect it against external shocks.

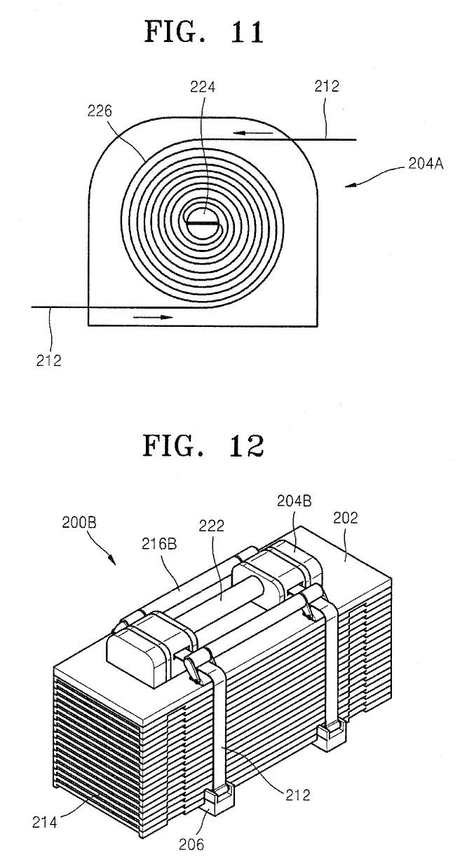

The apparatus 100A according to the current embodiment of the present invention further includes a plurality of belt drums 104, each belt drum 104 being attached to one side of the frame body 102 and having a belt 112 connected thereto. The belt 112 surrounds the stack of trays 114 to secure and band the stack of trays 114 using the elastic tension of a spring member (see element 224 in FIG. 11) mounted in the belt drum 104, where the spring member may include a spiral spring. The belt 112 can easily be wound or reeled by the belt drum 104. The belt 112 may be formed of a resin or textile material. The apparatus 100A of the current embodiment uses the belt 112 attached to the belt drum 104 to secure the stack of trays 114, thus preventing the trays from separating and significantly reducing the amount of foreign materials and particles distributed during handling, transportation, or storage of the stack of trays, as compared to a conventional tray clamping apparatus using a band with a Velcro adhesive.

The apparatus 100A further includes a hook 106 that is formed of metal or resin and is disposed to rotate from the side of the frame body 102 to contact a bottom surface of the stack of trays 114. The hook 106 may act as a clamp to support the bottom of the stack of trays 114 when the hook 106 is rotated so as to engage the bottom of the stack of trays 114.

The apparatus 100A may further include a hook-fixing unit 116 that is controlled by a hook-fixing lever 108A and fixes the hook 106 and the belt 112. When the hook-fixing lever 108A is pushed down, the hook 106 is rotated upwardly to engage the bottom of the stack of trays 114 and the belt 112 is tightened to secure the stack of trays therebetween. When the hook-fixing lever 108A is pulled up, the hook 106 and belt 112 are respectively released and loosened.

The apparatus 100A may further include a top cover 110 connected to the belt 112 to provide a fixed top for the stack of trays 114. The top cover 110 may be formed of a material similar to that of a tray 114. The top cover 110 may also suitably have a shape similar to that of a tray 114 so that the top cover corresponds to the top tray 114 in the stack of trays 114 and can press down on the top of the stack of trays 114 to fix and hold them in place. Although not shown, a hand grip may be fixed to the top cover 110 to allow easy handling and transportation of the stack of trays 114, as illustrated in FIG. 12.

Furthermore, a product information identifier 115 may be installed on the top cover 110 or at a specific location of the frame body 102 so that a product information scanning unit, such as a barcode reader or radio frequency identification (RFID) reader can easily recognize product information during the automation process. The product information identifier 115 may include a lot information card containing barcodes or an embedded RFID tag that can be used to identify lot information. The product information identifier 115 may also be consistently located in the same area on the top cover 110 or on the frame body 102 so that the product information scanning unit can automatically read the product information or lot information during various stages of the manufacturing process.

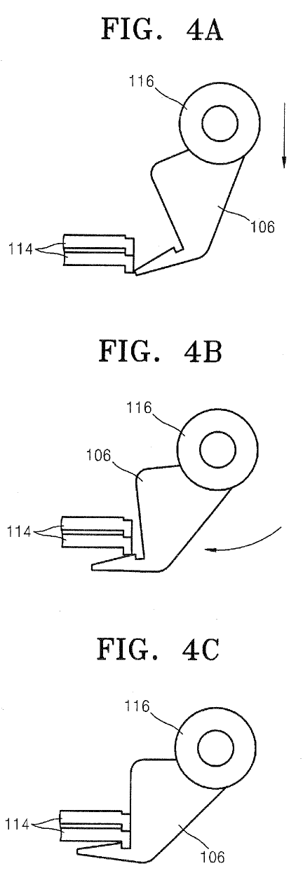

FIG. 3 is a side view of the hook 106 shown in the apparatus 100A of FIG. 2 and FIGS. 4A through 4C are side views illustrating the operation of the hook 106.

Referring to FIGS. 3 and 4, the hook-fixing unit 116 and the belt drum 104 rotate about a rotary axis A mounted in the frame body 102. Therefore, when the hook-fixing lever 108A (in FIG. 2) is pushed down, the belt 112 fixing the stack of trays 114 is tightened by the movement about the rotary axis A connected to the hook-fixing lever 108A. At the same time, the hook 106 is rotated in the order illustrated in FIGS. 4A through 4C. To this end, a separate locking element may be mounted in the hook-fixing unit 116 to prevent movement of the hook 106 when the hook-fixing lever 108A is pulled up or pushed down all the way.

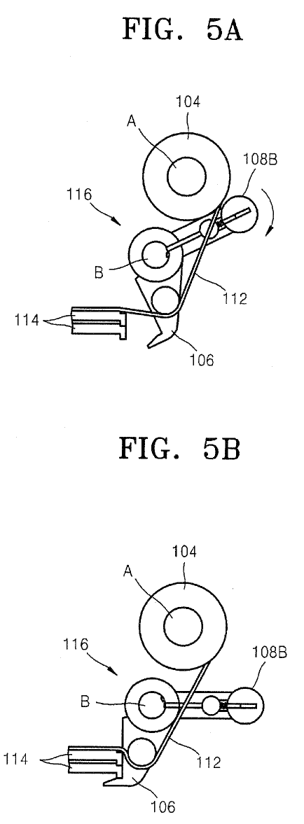

FIGS. 5A and 5B are side views illustrating the operation of a hook-fixing unit 116 in an apparatus for clamping a stack of trays according to another embodiment of the present invention.

Referring to FIGS. 5A and 5B, unlike the previous embodiment in which the belt drum 104 and the hook-fixing unit 116 rotate about the same rotary axis A as illustrated in FIG. 3, an apparatus for clamping a stack of trays according to this illustrated embodiment includes a separate rotary axis B that is connected to the hook-fixing lever 108B and a hook 106, where the belt 112 is connected to the hook 106 and is tightened by the movement of the hook 106 in response to the rotation of the hook-fixing lever 108B.

That is, the hook-fixing device 116 is driven using the rotary axis B connected to the belt 112, which in turn is driven using a rotary axis A of a belt drum 104. Thus, when the hook-fixing lever 108B is pushed down in the direction indicated by the arrow in FIG. 5A, the hook moves to support a bottom surface of a stack of trays 114, as illustrated in FIG. 5B. The apparatus according to the current embodiment uses only the belt 112 to fix the top of the stack of trays 114. That is, the apparatus does not include a separate top cover.

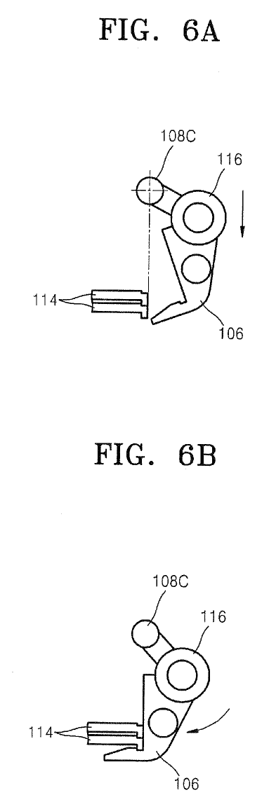

FIGS. 6A and 6B are side views illustrating the operation of a hook-fixing unit 116 in an apparatus for clamping a stack of trays according to another embodiment of the present invention.

Referring to FIGS. 6A and 6B, unlike in the embodiment illustrated in FIGS. 5A and 5B in which the hook-fixing unit 116 is formed around the rotary axis B, the apparatus according to the presently illustrated embodiment has a structure in which the hook 106 is inserted below a bottom surface of a stack of trays 114 by only conical movement when the hook-fixing lever 108C is moved. The rest of the structure and operation are the same as in the first embodiment, and thus a detailed description thereof will not be given to avoid redundancy.

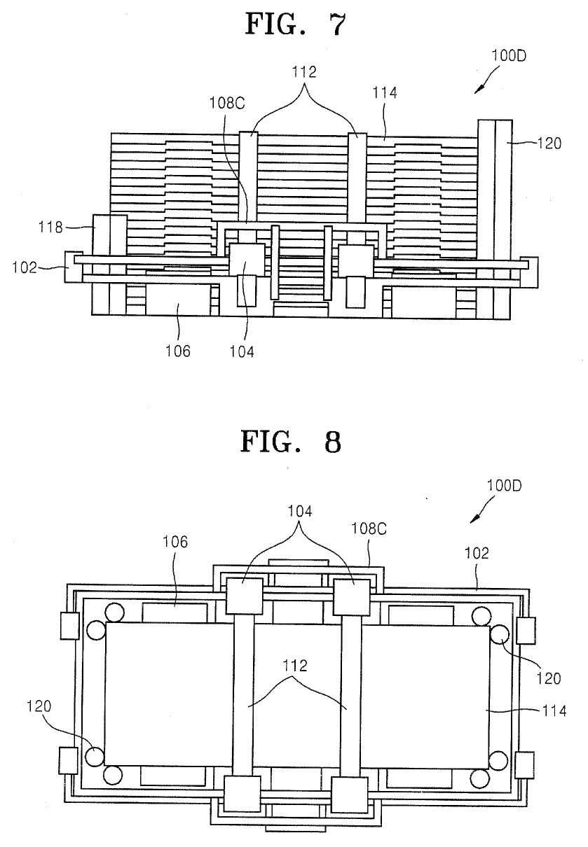

FIGS. 7 through 9 are a front view, a plan view, and a side view, respectively, illustrating a state in which an apparatus 100D for clamping a stack of trays has clamped the trays together into a stack of trays 114 according to another embodiment of the present invention.

Referring to FIGS. 7 through 9, the apparatus 100D according to the current embodiment may additionally use short and/or long corner guides 118 and 120, when necessary, to form the stack of trays 114. The rest of the structure and operation are the same as in the embodiment described with reference to FIGS. 6A and 6B, and thus a further detailed description will not be given to avoid redundancy.

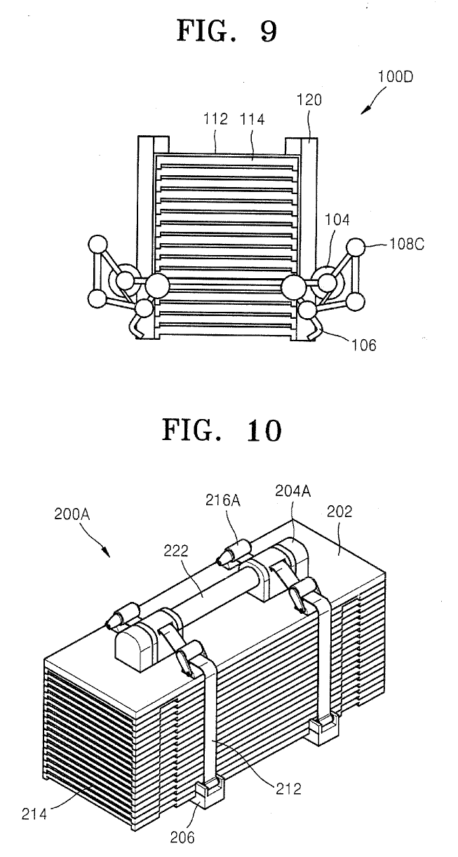

FIG. 10 is a perspective view of an apparatus 200A for clamping a stack of trays according to another embodiment of the present invention and FIG. 11 is a side view for explaining the operation of a belt drum 204A in the apparatus 200A.

Referring to FIGS. 10 and 11, the apparatus 200A includes a substantially planar frame body 202 covering the top of a stack of trays 214, a hand grip 222 for movement of the stack of trays 214, which is mounted on the frame body 202, a belt drum 204A with a belt 212 securely surrounding sidewalls of the stack of trays 214 using an elastic tension of a spiral spring member 224 (in FIG. 11 below), and a wedge-shaped hook 206 attached to a distal end of the belt 212 connected to the belt drum 204A and contacting a bottom surface of the stack of trays 214.

The length of the belt 212 should be adjusted according to the height of stack of trays 214 that typically varies depending on the number of trays in a lot. The belt drum 204A has a spiral spring member 224 to allow this adjustment. Thus, the belt 206 is wound in a circular fashion 226 within the belt drum 206A and has a restoring force due to the elastic tension of the spiral spring member 224 exerted in the direction indicated by arrows on FIG. 11.

The apparatus 200A may further include a belt fixing unit 216A that is mounted on the frame body 202 and fixes the belt 212 connected to the belt drum 204A.

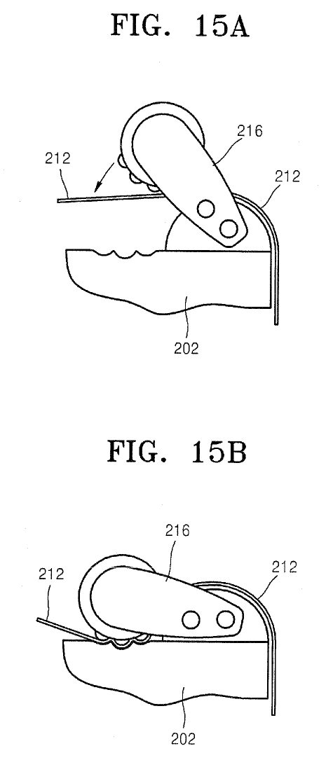

One feature of the present embodiment is that the frame body 202 has a substantially planar shape so as to correspond to the top portion of the stack of trays 214 and fix them in place. Another feature is that the stack of trays 214 is banded by the belt 212 having an elastic tension in two directions due to the spiral spring member 224 within the belt drum 204. The belt fixing unit 216A fixes the belt 212 after the hook 206 is inserted below a bottom surface of the stack of trays 214 to tighten the stack of trays 214. The operation principle of the belt fixing device 216A will be described below in further detail with reference to FIG. 15.

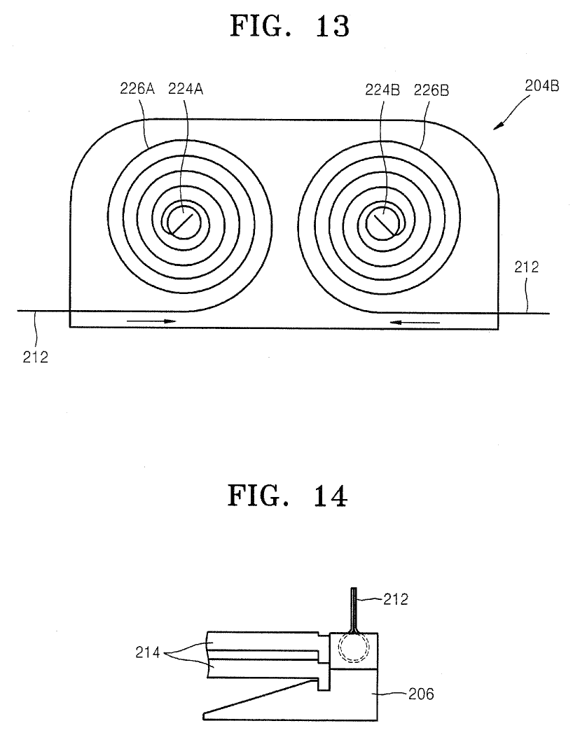

FIG. 12 is a perspective view of an apparatus 200B for clamping a stack of trays according to another embodiment of the present invention and FIG. 13 is a side view illustrating the operation of a belt drum 204B in the apparatus 200B.

Referring to FIGS. 12 and 13, unlike the embodiment illustrated in FIGS. 10 and 11 using one spiral spring member 224 within the belt drum 204A, the apparatus 204B has two spiral springs 224A and 224B to tighten two belts 212 in two opposite directions forming two wound-up portions 226A and 226B of the belts 212. Furthermore, in the current embodiment, a belt fixing unit 216B can tighten two belts 212 as illustrated in FIG. 12. The rest of the structure and operation are similar to the embodiment described with reference to FIGS. 10 and 11, and thus a further detailed description will not be given to avoid redundancy.

FIG. 14 is a side view illustrating the shape and function of the hooks 206 employed in the apparatuses of FIGS. 10 and 12.

Referring to FIG. 14, the hook 206 has a wedge shape to allow easy sliding under a bottom surface of the stack of trays 214. The wedge-shaped hook 206 has a groove that can engage with a portion of the bottom of the stack of trays 214. This structure enables the stack of trays 214 to be supported when the stack of trays 214 is secured by tightening the belt 212. The hook 206 may be formed of metal or resin. The shape of the hook 206 can be applied in the same manner to the first through fourth embodiments.

FIGS. 15A and 15B are side views illustrating the operation principle of the belt-fixing units 216A and 216B in the apparatuses of FIGS. 10 and 12.

Referring to FIGS. 15A and 15B, the belt-fixing units 216 may be structured as belt-fixing levers, which secure and fix the belt 212 by pushing down on the belt 212. FIG. 15A illustrates a state in which the belt 212 is released by pulling up the belt-fixing unit 216 and FIG. 15B illustrates a state in which the belt 212 is tightened by pushing down the belt-fixing unit 216. To achieve this function, the belt-fixing unit 216 has protrusions on a lower surface thereof, which can engage into corresponding depressions formed in the frame body 202. Those skilled in the art will appreciate that other various structures of the belt fixing units 216 are possible.

Furthermore, in the apparatuses 200A and 200B of the present invention, a product information identifier (not shown), such as a lot information card containing barcodes or an RFID tag, may be attached to a specific location of the frame body 200, thus enabling handling and transportation of the stack of trays 214 using automation equipment.

As described above, a novel apparatus for clamping a stack of trays according to the present invention has the following advantages.

First, the apparatus uses a belt drum, a hook-fixing unit, and a belt-fixing unit to secure or separate a stack of trays, thus allowing easy process automation. This in turn reduces the need of manual operations that may be cumbersome.

Second, the apparatus has a hand grip to ensure easy and comfortable manual handing and transportation.

Third, the apparatus eliminates the use of a fastening means such as Velcro, thus minimizing the amount of contaminants such as particles that can be distributed during the fabrication of semiconductor devices.

Fourth, the apparatus eliminates the need for a carrier box during a semiconductor package fabrication process, thus allowing efficient utilization of a space for storing a stack of trays.

Fifth, the apparatus allows a product information identifier such as a lot information card with barcodes or an RFID tag to be attached to a specific location, thus enabling easy automatic recognition of product information using automation equipment and facilities.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for clamping a stack of trays comprising:
a frame body surrounding the stack of trays;
a plurality of belt drums, each belt drum being attached to one side of the frame body and having a belt connected thereto, wherein the belt is configured to surround the stack of trays to secure the stack of trays using an elastic tension of a spring member mounted in the belt drum; and
a hook connected to the frame body, the hook configured to slide under a bottom surface of the stack of trays.

2. The apparatus of claim 1, wherein the frame body is a substantially rectangular structure surrounding lateral sides of the stack of trays.

3. The apparatus of claim 2, wherein the frame body further comprises a hook-fixing unit connected to the hook, the hook-fixing unit configured to rotate about the frame body.

4. The apparatus of claim 3, further comprising a hook-fixing lever connected to the hook fixing unit, wherein the hook-fixing lever is structured to rotate the hook-fixing unit about the frame body to slide the hook under the bottom surface of the stack of trays.

5. The apparatus of claim 2, further comprising a top cover connected to the belt, the top cover configured to correspond to a top portion of the stack of trays.

6. The apparatus of claim 5, wherein a hand grip is attached to the top cover to allow easy handling of the stack of trays.

7. The apparatus of claim 5, wherein the top cover has a product information identifier embedded therein.

8. The apparatus of claim 5, wherein the top cover is substantially planar and is formed of the same material as the trays.

9. The apparatus of claim 1, wherein the frame body is a substantially planar frame body mounted on a top portion of the stack of trays.

10. The apparatus of claim 9, wherein the substantially planar frame body further comprises a belt-fixing unit connected to the substantially planar frame body, the belt-fixing unit structured to secure the belt in order to secure the stack of trays.

11. The apparatus of claim 10, wherein the belt-fixing unit includes a belt-fixing lever, the belt-fixing lever configured to secure the belt in at least one position.

12. The apparatus of claim 9, further comprising a hand grip attached to a top portion of the substantially planer frame body to allow easy handling of the stack of trays.

13. The apparatus of claim 1, wherein a product information identifier is embedded in the frame body.

14. The apparatus of claim 1, wherein the hook is formed of at least one of metal or resin.

15. The apparatus of claim 1, wherein the hook includes a wedge-shaped portion to allow the hook to slide under the bottom surface of the stack of trays.

16. The apparatus of claim 9, wherein the hook is connected to the frame body through the belt.

17. An apparatus for clamping a stack of trays, comprising:
a substantially rectangular frame body surrounding the stack of trays;
a belt drum mounted on the frame body and having a belt surrounding the stack of trays using an elastic tension of a spiral spring member mounted therein;
a substantially planar top cover connected to the belt and having a hand grip for handling the apparatus, the substantially planar top cover configured to secure a top portion of the stack of trays;
a wedge-shaped hook connected to the frame body, the wedge-shaped hook structured to slide under a bottom surface of the stack of trays; and
a hook-fixing unit mounted on the frame body and connected to the wedge-shaped hook, the hook-fixing unit configured to secure the wedge-shaped hook under the bottom surface of the stack of trays.

18. The apparatus of claim 17, wherein one of the top cover and the frame body has a product information identifier embedded therein.

19. An apparatus for clamping a stack of trays, comprising:
a substantially planar frame body covering a top portion of the stack of trays;
a hand grip disposed on the substantially planar frame body;
a belt drum mounted on the substantially planar frame body and including a belt securely surrounding a sidewall of the stack of trays using an elastic tension of a spiral spring member mounted therein;
a wedge-shaped hook attached to a distal end of the belt from the belt drum, the wedge-shaped hook configured to slide under a bottom surface of the stack of trays; and
a belt fixing unit mounted on the substantially planer frame body to secure the belt.

20. The apparatus of claim 19, wherein the frame body has a product information identifier embedded therein.
